(19) United States
(12) Patent Application Publication
(10) Pub. No.: US 2021/0383039 A1
(43) Pub. Date: Dec. 9, 2021

(54) METHOD AND SYSTEM FOR MULTILAYER MODELING

(71) Applicant: INSTITUTE FOR INFORMATION INDUSTRY, Taipei (TW)

(72) Inventors: Cheng-Juei YU, Taipei (TW); Cheng-Hung WU, Taipei (TW); Yu-Hsin CHANG, Taipei (TW)

(73) Assignee: INSTITUTE FOR INFORMATION INDUSTRY, Taipei (TW)

(21) Appl. No.: 16/931,150

(22) Filed: Jul. 16, 2020

(30) Foreign Application Priority Data
Jun. 5, 2020 (TW) 109118988

(51) Int. Cl. G06F 30/27

(52) U.S. Cl. CPC G06F 30/27

(57) ABSTRACT

A method and a system for multilayer modeling are provided. The system includes a processing unit and a model building and training unit. The processing unit is configured to obtain an original data from a storage unit, obtain plural data sets of the fundamental combinations, plural data sets of the partial combinations and a data set of the full combination from the original data according to plural categorical variables of the original data, and divide the data set of each of the fundamental combinations, the data set of each of the partial combinations and the data set of the full combination into a training data set, a validation data set and a testing data set to obtain plural training data sets, plural validation data sets and plural testing data sets. The model building and training unit is configured to build plural models respectively according to the training data sets.

This application claims the benefit of Taiwan application Serial numbering 109118988, filed Jun. 5, 2020, the disclosure of which is incorporated by reference herein in its entirety.

### TECHNICAL FIELD

The disclosure relates in general to a multilayer modeling method, and more particularly to a method and a system for multilayer modeling.

### BACKGROUND

The manufacturing industries normally involve complicated production processes. Different combinations of materials and equipment will lead to different production throughputs. Non-numerical variables related to materials and equipment are referred as categorical variables, such as material types, machine types, and recipe types. Also, different combinations of categorical variables will lead to different production throughputs. The prediction of production throughput relates to the arrangement of raw materials, the determination of delivery dates and the negotiation of orders. In the prior art, the building of single predictive model for production throughput is based on total data. Since the combinations of different categorical variables may have a large difference in terms of data distribution, the single predictive model built according to the total data may lead to a poor accuracy in prediction. Furthermore, single predictive model cannot accurately predict the production throughput for each combination of categorical variables. Besides, the process engineer cannot judge whether the predictive result of the single predictive model is reasonable with respect to some of the combinations of categorical variables.

Therefore, the invention provides a method and a system for multilayer modeling for capable of resolving the abovementioned problems of single predictive model.

### SUMMARY

The invention is directed to a method and a system for multilayer modeling capable of building and training the models of different sizes according to the data sets of various combinations of categorical variables (fundamental combinations, partial combinations and full combination) and selecting a preferable predictive model through validating and testing.

According to one embodiment of the invention, a multilayer modeling system is provided. The system includes a processing unit and a model building and training unit. The processing unit is configured to obtain an original data from a storage unit, obtain a plurality of data sets of the fundamental combinations, a plurality of data sets of the partial combinations and a data set of the full combination from the original data according to a plurality of categorical variables of the original data, and divide the data set of each of the fundamental combinations, the data set of each of the partial combinations and the data set of the full combination into a training data set, a validation data set and a testing data set respectively to obtain a plurality of training data sets, a plurality of validation data sets and a plurality of testing data sets. The model building and training unit is configured to build a plurality of models respectively according to the training data sets. The data sets of the fundamental combinations are data sets in which each of the categorical variables is a specific attribute value. The data sets of the partial combinations are data sets, in which at least one of the categorical variables is an arbitrary attribute value, but exclude the data sets, in which each of the categorical variables is the arbitrary attribute value. The data set of the full combination is the data set, in which each of the categorical variables is an arbitrary attribute value.

According to another embodiment of the invention, a multilayer modeling method is provided. The method includes the following steps: An original data is obtained. A plurality of data sets of the fundamental combinations, a plurality of data sets of the partial combinations and a data set of the full combination are obtained from the original data according to a plurality of categorical variables of the original data. The data set of each of the fundamental combinations, the data set of each of the partial combinations and the data set of the full combination are divided into a training data set, a validation data set and a testing data set respectively to obtain a plurality of training data sets, a plurality of validation data sets and a plurality of testing data sets. A plurality of models are respectively built according to the training data sets. The data sets of the fundamental combinations are data sets, in which each of the categorical variables is a specific attribute value. The data sets of the partial combinations are data sets, in which at least one of the categorical variables is an arbitrary attribute value, but exclude the data sets, in which each of the categorical variables is the arbitrary attribute value. The data set of the full combination is the data set, in which each of the categorical variables is an arbitrary attribute value.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a schematic diagram of a multilayer modeling system.

FIG. 2 is a flowchart of a multilayer modeling method according to an embodiment.

FIG. 3 is a schematic diagram of an original data, a plurality of data sets of the fundamental combinations, a plurality of data sets of the partial combinations and a data set of the full combination according to an embodiment.

FIG. 4 is a schematic diagram of a plurality of training data sets, a plurality of validation data sets and a plurality of testing data sets obtained from the data sets of the fundamental combinations, the data sets of the partial combinations and the data set of the full combination according to an embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

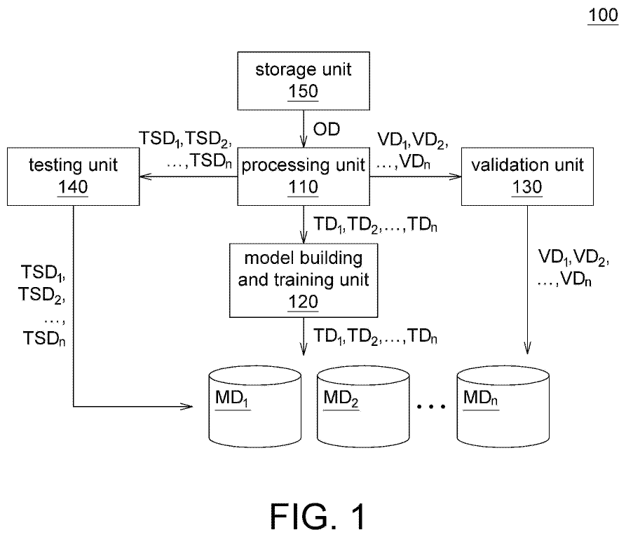

Referring to FIG. 1, a schematic diagram of a multilayer modeling system 100 is shown. The multilayer modeling system 100 includes a processing unit 110, a model building and training unit 120, a validation unit 130, a testing unit 140 and a storage unit 150. The processing unit 110, the model building and training unit 120, the validation unit 130 and the testing unit 140 can be realized by such as a chip, a circuit board, a circuit, a number of programming codes, or a storage device storing programming codes. The storage unit 150 can be realized by such as a memory or a hard disc. In an embodiment, the storage unit 150 can be an external storage unit of the system 100.

Detailed descriptions of the operation of the multilayer modeling system 100 are disclosed below with a flowchart chart.

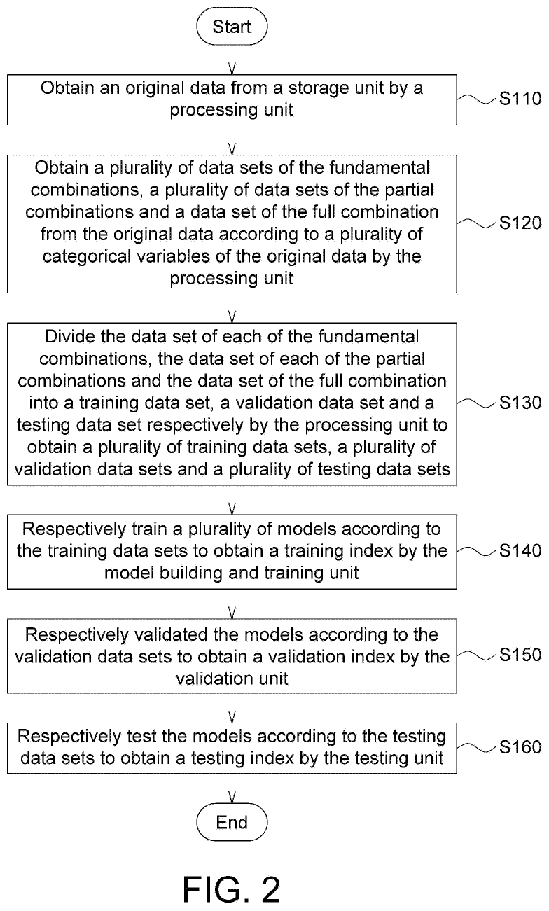

Refer to FIGS. 1 and 2. FIG. 2 is a flowchart of a multilayer modeling method according to an embodiment. Firstly, the method begins at step S110, an original data OD is obtained from a storage unit 150 by the processing unit 110, wherein the original data OD at least includes a plurality of categorical variables. Refer to Table 1. Table 1 is an example of the original data OD composed of 13,186 items of data. The original data OD includes a numerical variable, five categorical variables, a plurality of numerical variables and a response variable which represents the units-per-hour (UPH) in this example. The five categorical variables respectively are: “Material”, “Product”, “Machine”, “Process” and “Recipe”, wherein each of the categorical variables includes a plurality of attribute values. For example, the categorical variable “Material” includes two attribute values, namely, “Material 1” and “Material 2”. Both the numerical variables and the response variable are numerical. Let the data of numbering 1 of Table 1 be taken for example. The content of the numerical variable is represented by numerical values “5.5 . . . 42.6”. Table 1 illustrates the original data OD of the production process of a manufacturing industry, wherein the categorical variables of the original data OD refer to non-numerical variables in the production process, namely, material, product, machine, process and recipe. The attribute values represent the non-numerical content of the categorical variables, such as types and models. For example, the two types of materials are represented by attribute values “Material 1” and “Material 2” respectively.

TABLE 1

| | | | | | | Numerical | |
|---|---|---|---|---|---|---|---|
| Numbering | Material | Product | Machine | Process | Recipe | variables | UPH |
| 1 | Material 1 | Product 1 | Machine 1 | Process 1 | Recipe 1 | 5.5 . . . 42.6 | 1546.2 |
| 2 | Material 1 | Product 1 | Machine 1 | Process 5 | Recipe 7 | 4.3 . . . 32.3 | 1261.4 |
| 3 | Material 1 | Product 1 | Machine 3 | Process 2 | Recipe 2 | 5.8 . . . 22.2 | 860 |
| 4 | Material 2 | Product 1 | Machine 2 | Process 2 | Recipe 18 | 6.8 . . . 32.8 | 895.5 |
| 5 | Material 2 | Product 2 | Machine 2 | Process 2 | Recipe 1 | 3.1 . . . 31.7 | 892 |
| 6 | Material 2 | Product 2 | Machine 7 | Process 3 | Recipe 3 | 5.5 . . . 32.6 | 877.36 |
| 7 | Material 1 | Product 2 | Machine 1 | Process 3 | Recipe 14 | 4.5 . . . 32.6 | 873 |
| . . . | . . . | . . . | . . . | . . . | . . . | . . . | . . . |
| . . . | . . . | . . . | . . . | . . . | . . . | . . . | . . . |
| 13185 | Material 1 | Product 3 | Machine 2 | Process 1 | Recipe 4 | 15 . . . 52.8 | 1415 |
| 13186 | Material 2 | Product 3 | Machine 4 | Process 6 | Recipe 4 | 18.4 . . . 33.6 | 1420 |

For the convenience of explanation, here below it is exemplified that the original data OD includes five categorical variables A, B, C, D and E, wherein the categorical variable A includes two attribute values a1 and a2; the categorical variable B includes three attribute values b1, b2 and b3; the categorical variable C includes four attribute values c1, c2, c3 and c4; the categorical variable D includes seven attribute values d1, d2, . . . , and d7; the categorical variable E includes twenty two attribute values e1, e2, e22; and the original data OD contains 13,186 rows of observations.

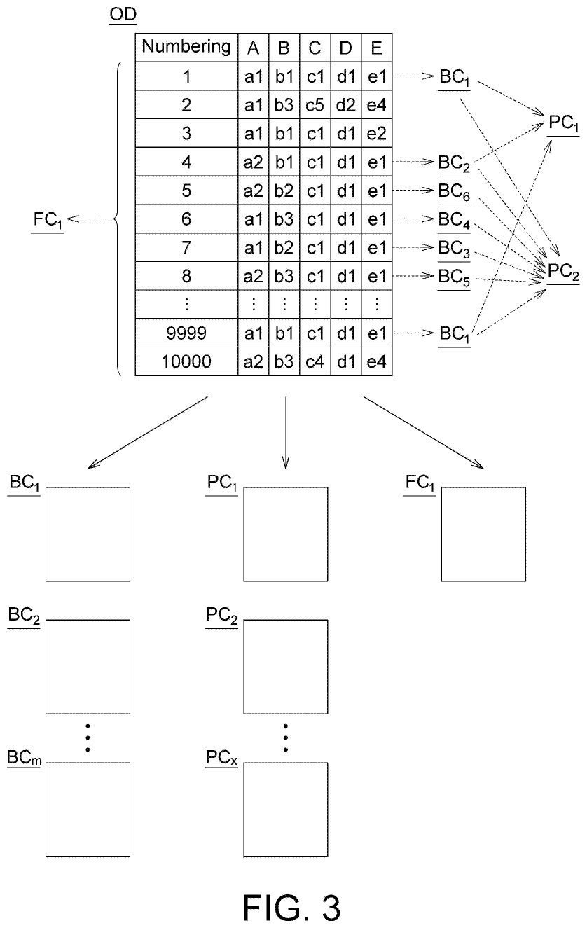

Refer to FIGS. 1-3. FIG. 3 is a schematic diagram of original data OD, a plurality of data sets of the fundamental combinations BC₁, . . . , BCₘ, a plurality of data sets of the partial combinations PC₁, . . . , PCₓ and a data set of the full combination FC₁ according to an embodiment. Next, the method proceeds to step S120, a plurality of data sets of the fundamental combinations BC₁, . . . , BCₘ, a plurality of data sets of the partial combinations PC₁, . . . , PCₓ and a data set of the full combination FC₁ are obtained from the original data OD by the processing unit 110 according to a plurality of categorical variables A, B, C, D and E of the original data OD.

Fundamental combinations BC₁, BCₘ represent that each of the categorical variables A, B, C, D and E is a specific attribute value. For example, the fundamental combination (such as the fundamental combination BC₁ of FIG. 3), in which the categorical variable A is an attribute value a1, the categorical variable B is an attribute value b1, the categorical variable C is an attribute value c1, the categorical variable D is an attribute value d1, and the categorical variable E is an attribute value e1, can be represented as: {A,B,C,D,E}={a1,b1,c1,d1,e1}, another fundamental combination (such as the fundamental combination BC₂ of FIG. 3), in which the categorical variable A is an attribute value a2, the categorical variable B is an attribute value b1, the categorical variable C is an attribute value c1, the categorical variable D is an attribute value d1, and the categorical variable E is an attribute value e1, can be represented as: {A,B,C,D,E}={a2,b1,c1,d1,e1}. The rest fundamental combinations can be obtained by the same analogy and are not illustrated one by one here. In the present example, the fundamental combinations BC₁, BCₘ have 2×3×4×7×22=3,696 combinations. Of the original data OD, the data matching the fundamental combinations BC₁, . . . , BCₘ form a plurality of data sets of the fundamental combinations BC₁, . . . , BCₘ. The data sets of distinct fundamental combinations BC₁, . . . , BCₘ are mutually exclusive. In an embodiment, the processing unit 110 deletes the fundamental combinations not including any data.

Full combination FC₁ represents that each of the categorical variables is an arbitrary attribute value, and is represented by “+” here below, wherein the arbitrary attribute value “+” represents that each of the categorical variables can be any of the attribute values. For example, if the categorical variable A is an arbitrary attribute value “+”, this implies that the categorical variable A can be attribute value a1 or a2; if the categorical variable B is an arbitrary attribute value “+”, this implies that the categorical variable B can be attribute value b1 or b2 or b3. The rest categorical variables can be obtained by the same analogy.

The combination, in which the categorical variable A is an arbitrary attribute value “+”, the categorical variable B is an arbitrary attribute value “+”, the categorical variable C is an arbitrary attribute value “+”, the categorical variable D is an arbitrary attribute value “+”, and the categorical variable E is an arbitrary attribute value “+”, is a full combination (such as full combination FC₁ of FIG. 3), and can be represented as: {A,B,C,D,E}={+,+,+,+,+}. In the present example, there is only one full combination FC₁. Of the original data OD, the data matching the full combination FC₁ form the data set of the full combination FC₁. It should be noted that the data set of the full combination FC₁ is composed of the data sets of a totality of the fundamental combinations BC₁, . . . , BCₘ.

Partial combinations PC₁, . . . , PCₓ represent that at least one of the categorical variables is an arbitrary attribute value, but exclude the combination, in which each of the categorical variables is the arbitrary attribute value (that is, excludes the data set of the full combination). For example, the partial combination (such as the partial combination PC₁ of FIG. 3), in which the categorical variable A is an arbitrary attribute value “+” (a1 or a2), the categorical variable B is an attribute value b1, the categorical variable C is an attribute value c1, the categorical variable D is an attribute value d1, and the categorical variable E is an attribute value e1 (that is, one categorical variable is an arbitrary attribute value but the other four categorical variables are specific attribute value), can be represented as: {A,B,C,D,E}={+,b1,c1,d1,e1}, another partial combination (such as partial combination PC₂ of FIG. 3, in which the categorical variable A is an arbitrary attribute value “+” (a1 or a2), the categorical variable B is an arbitrary attribute value “+” (b1 or b2 or b3), the categorical variable C is an attribute value c1, the categorical variable D is an attribute value d1, and the categorical variable E is an attribute value e1 (that is, two categorical variables are arbitrary attribute values but the other three categorical variables are specific attribute values), can be represented as: {A,B,C,D,E}={+,+,c1,d1,e1}. The rest partial combinations can be obtained by the same analogy and are not illustrated one by one here. Of the original data OD, the data matching partial combinations PC₁, . . . , PCₓ form the data sets of the partial combinations PC₁, . . . , PCₓ. It should be noted that the data set of each of the partial combinations PC₁, . . . , PCₓ is composed of data sets of a plurality of the fundamental combinations BC₁, . . . , BCₘ. As indicated in FIG. 3, the data set of the partial combination PC₁ is composed of the data sets of the fundamental combinations BC₁ and BC₂, and the data set of the partial combination PC₂ is composed of the data sets of the fundamental combinations BC₁, BC₂, BC₃, BC₄, BC₅, BC₆. That is, the data sets of distinct partial combinations PC₁, . . . , PCₓ are not mutually exclusive.

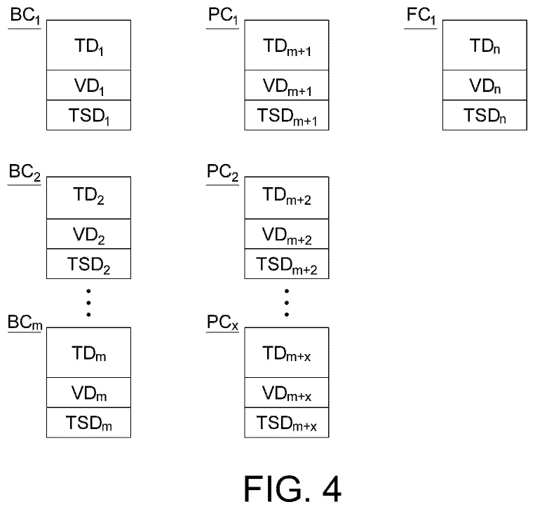

FIG. 4 is a schematic diagram of a plurality of training data sets T₁, . . . , TDₙ, a plurality of validation data sets VD₁, . . . , VDₙ and a plurality of testing data sets TSD₁, . . . , TSDₙ obtained from the data sets of the fundamental combinations BC₁, . . . , BCₘ, the data sets of the partial combinations PC₁, . . . , PCₓ and the data set of the full combination FC₁ according to an embodiment. Then, the method proceeds to step S130, the data set of each of the fundamental combinations BC₁, . . . , BCₘ, the data set of each of the partial combinations PC₁, . . . , PCₓ and the data set of the full combination FC₁ are divided into a training data set, a validation data set and a testing data set respectively by the processing unit 110 to obtain a plurality of training data sets TD₁, . . . , TDₙ, a plurality of validation data sets VD₁, . . . , VDₙ and a plurality of testing data sets TSD₁, . . . , TSDₙ.

To put it in greater details, the processing unit 110 divides the data set of each of the fundamental combinations BC₁, . . . , BCₘ, the data set of each of the partial combinations PC₁, . . . , PCₓ and the data set of the full combination FC₁ into three portions respectively. The first portion in each of the data sets is used as the training data sets TD₁, . . . , TDₙ, the second portion in each of the data sets is used as the validation data sets VD₁, . . . , VDₙ, and the third portion in each of the data sets is used as the testing data sets TSD₁, . . . , TSDₙ, wherein the first portion, the second portion and the third portion in each of the data sets are mutually exclusive. In an embodiment, the first portion, the second portion and the third portion respectively occupy 70%, 15% and 15%, but the invention is not limited the said exemplification. Let the data set of the fundamental combination BC₁ be taken for example. If the first portion, the second portion and the third portion occupy 70%, 15% and 15% respectively, then the processing unit 110 respectively allocates 70%, 15% and 15% of the data set of the fundamental combination BC₁ as the training data set TD₁, the validation data set VD₁, and the testing data set TSD₁.

It can be understood from the above descriptions of the partial combinations that the data set of each of the partial combinations PC₁, . . . , PCₓ is composed of data sets of a plurality of the fundamental combinations BC₁, . . . , BCₘ. Therefore, the training data sets TDₘ₊₁, . . . , TDₘ₊ₓ of each of the partial combinations PC₁, . . . , PCₓ are composed of the training data sets of a plurality of the fundamental combinations; the validation data sets VDₘ₊₁, . . . , VDₘ₊ₓ of each of the partial combinations PC₁, . . . , PCₓ are composed of the validation data sets of a plurality of the fundamental combinations; and the testing data sets TSDₘ₊₁, . . . , TSDₘ₊ₓ of each of the partial combinations PC₁, . . . , PCₓ are composed of the testing data sets of a plurality of the fundamental combinations. For example, if the partial combination PC₁ is composed of the fundamental combinations BC₁ and BC₂, then the training data set TDₘ₊₁ of the partial combination PC₁ is composed of the training data set TD₁ of the fundamental combination BC₁ and the training data set TD₂ of the fundamental combination BC₂; the validation data set VDₘ₊₁ of the partial combination PC₁ is composed of the validation data set VD₁ of the fundamental combination BC₁ and the validation data set VD₂ of the fundamental combination BC₂; and the testing data set TSDₘ₊₁ of the partial combination PC₁ is composed of the testing data set TSD₁ of the fundamental combination BC₁ and the testing data set TSD₂ of the fundamental combination BC₂.

It can be understood from the above descriptions of the full combination that the data set of the full combination FC₁ is composed of the data sets of a totality of the fundamental combinations BC₁, . . . , BCₘ. Therefore, the training data set TDₙ of the full combination FC₁ is composed of the training data sets of a totality of the fundamental combinations; the validation data set of the full combination FC₁ is composed of the validation data sets of a totality of the fundamental combinations; and the testing data set of the full combination FC₁ is composed of the testing data sets of a totality of the fundamental combinations. For example, the training data set TDₙ of the full combination FC₁ is composed of the training data sets TDₙ of each of the fundamental combinations BC₁, . . . , BCₘ; the validation data set VDₙ of the full combination FC₁ is composed of the validation data sets VD₁, . . . , VDₘ of each of the fundamental combinations BC₁, . . . , BCₘ; and the testing data set TSDₙ of the full combination FC₁ is composed of the testing data sets TSD₁, . . . , TSDₘ of each of the fundamental combinations BC₁, . . . , BCₘ.

In step S140, a plurality of models MD₁, MD₂, . . . , MDₙ are respectively built and trained by the model building and training unit 120 according to the training data sets TD₁, TDₙ to obtain ta training index. In an embodiment, the training index can be root mean square error (RMSE), 90% Quantile, mean absolute percentage error (MAPE) or mean absolute error (MAE), but the invention is not limited thereto.

In step S150, the models MD₁, MD₂, . . . , MDₙ are respectively validated by the validation unit 130 according to the validation data sets VD₁, . . . , VDₙ to obtain ta validation index, and a preferable model is selected from a plurality of models MD₁, MD₂, . . . , MDₙ by the validation unit 130 according to the validation index. In an embodiment, the validation index can be RMSE, 90% Quantile, MAPE or MAE, but the invention is not limited thereto.

In step S160, the models MD₁, MD₂, . . . , MDₙ are respectively tested by the testing unit 140 according to the testing data sets TSD₁, . . . , TSDₙ to obtain ta testing index. The selected model by the validation unit 130 is marked by the testing unit 140 according to the testing index. In an embodiment, the testing index can be RMSE, 90% Quantile, MAPE or MAE, but the invention is not limited thereto.

Let the UPH prediction of the order of semiconductor packaging process be taken for example. In practical application, an optimum predictive model, such as the model built according to the data sets matching the combination of categorical variables {2,+,+,6,18}, can be obtained according to the information of the categorical variables (that is, material 2, product 1, machine 3, process 6, and recipe 18) used in the production process together with the values of the numerical variables of the order, such as the grain length, the grain width, the grain grinding thickness, the grain line number, the grain line length, the grain line width and the number of grains carried on the grain substrate obtained before the packaging process is performed as well as the chip length, the chip width, the chip height and the chip pin count obtained after the packaging process is performed. Then, the above values can be introduced to the predictive model to obtain a predictive UPH of the order.

According to the system 100 of the invention, the models of different sizes are built and trained according to the data sets of various combinations of categorical variables (fundamental combinations, partial combinations and full combination), a preferable predictive model is selected through validating and testing, and a more accurate predictive model can be provided under various combinations of categorical variables. Moreover, since the system 100 of the invention can build the models of different sizes according to the data sets of various combinations of categorical variables (fundamental combinations, partial combinations and full combination) and can trace the sub-data sets used in each of the models built in the invention, the process engineer can judge whether the predictive result is reasonable and determine the factor influence.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A multilayer modeling system, comprising:
a processing unit configured to obtain an original data from a storage unit, obtain a plurality of data sets of the fundamental combinations, a plurality of data sets of the partial combinations and a data set of the full combination from the original data according to a plurality of categorical variables of the original data, and divide the data set of each of the fundamental combinations, the data set of each of the partial combinations and the data set of the full combination into a training data set, a validation data set and a testing data set respectively to obtain a plurality of training data sets, a plurality of validation data sets and a plurality of testing data sets; and
a model building and training unit configured to build a plurality of models respectively according to the training data sets;
wherein the data sets of the fundamental combinations are data sets, in which each of the categorical variables is a specific attribute value, the data sets of the partial combinations are data sets, in which at least one of the categorical variables is an arbitrary attribute value, but exclude the data sets, in which each of the categorical variables is the arbitrary attribute value, and the data set of the full combination is the data set, in which each of the categorical variables is an arbitrary attribute value.

2. The system according to claim 1, wherein the model building and training unit trains the models respectively according to the training data sets to obtain a training index.

3. The system according to claim 2, further comprising:
a validation unit configured to validate the models respectively according to the validation data sets to obtain a validation index.

4. The system according to claim 3, further comprising:
a testing unit configured to test the models respectively according to the testing data sets to obtain a testing index.

5. The system according to claim 4, wherein the training index, the validation index and the testing index are RMSE, 90% Quantile, MAPE or MAE.

6. The system according to claim 1, wherein the data set of each of the partial combinations is composed of the data sets of a part of the fundamental combinations.

7. The system according to claim 1, wherein the data set of the full combination is composed of the data sets of a totality of the fundamental combinations.

8. The system according to claim 1, wherein the training data set of each of the partial combinations is composed of the training data sets of a part of the fundamental combinations, the validation data set of each of the partial combinations is composed of the validation data sets of a part of the fundamental combinations, and the testing data set of each of the partial combinations is composed of the testing data sets of a part of the fundamental combinations.

9. The system according to claim 1, wherein the training data set of the full combination is composed of the training data sets of a totality of the fundamental combinations, the validation data set of the full combination is composed of the validation data sets of a totality of the fundamental combinations, and the testing data set of the full combination is composed of the testing data sets of a totality of the fundamental combinations.

10. A multilayer modeling method, comprising:
obtaining an original data;
obtaining a plurality of data sets of the fundamental combinations, a plurality of data sets of the partial combinations and a data set of the full combination from the original data according to a plurality of categorical variables of the original data;
dividing the data set of each of the fundamental combinations, the data set of each of the partial combinations and the data set of the full combination into a training data set, a validation data set and a testing data set respectively to obtain a plurality of training data sets, a plurality of validation data sets and a plurality of testing data sets; and
building a plurality of models respectively according to the training data sets;
wherein the data sets of the fundamental combinations are data sets, in which each of the categorical variables is a specific attribute value, the data sets of the partial combinations are data sets, in which at least one of the categorical variables is an arbitrary attribute value, but exclude the data sets, in which each of the categorical variables is the arbitrary attribute value, and the data set of the full combination is the data set, in which each of the categorical variables is an arbitrary attribute value.

11. The method according to claim 10, further comprising:
training the models respectively according to the training data sets to obtain a training index.

12. The method according to claim 11, further comprising:
validating the models respectively according to the validation data sets to obtain a validation index.

13. The method according to claim 12, further comprising:
testing the models respectively according to the testing data sets to obtain a testing index.

14. The method according to claim 13, wherein the training index, the validation index and the testing index are RMSE, 90% Quantile, MAPE or MAE.

15. The method according to claim 10, wherein the data set of each of the partial combinations is composed of the data sets of a part of the fundamental combinations.

16. The method according to claim 10, wherein the data set of the full combination is composed of the data sets of a totality of the fundamental combinations.

17. The method according to claim 10, wherein the training data set of each of the partial combinations is composed of the training data sets of a part of the fundamental combinations, the validation data set of each of the partial combinations is composed of the validation data sets of a part of the fundamental combinations, and the testing data set of each of the partial combinations is composed of the testing data sets of a part of the fundamental combinations.

18. The method according to claim 10, wherein the training data set of the full combination is composed of the training data sets of a totality of the fundamental combinations, the validation data set of the full combination is composed of the validation data sets of a totality of the fundamental combinations, and the testing data set of the full combination is composed of the testing data sets of a totality of the fundamental combinations.
